(19) United States
(12) Patent Application Publication
(10) Pub. No.: US 2012/0240855 A1
(43) Pub. Date: Sep. 27, 2012

(54) TRANSMISSION MECHANISM AND THE DEPOSITION APPARATUS USING THE SAME

(75) Inventors: Chen-Chung Du, Hsinchu City (TW); Ming-Tung Chiang, Hsinchu City (TW); Muh-Wang Liang, Miaoli County (TW); Kuan-Chou Chen, Hsinchu City (TW); Tean-Mu Shen, Hsinchu City (TW); Jung-Chen Ho, Hsinchu City (TW)

(73) Assignee: INDUSTRIAL TECHNOLOGY RESEARCH INSTITUTE, Hsin-Chu (TW)

(21) Appl. No.: 13/177,006

(22) Filed: Jul. 6, 2011

(30) Foreign Application Priority Data
Mar. 22, 2011 (TW) 100109636

(51) Int. Cl. C23C 16/50; F16H 57/00

(52) U.S. Cl. 118/723 R; 74/412 R

(57) ABSTRACT

The deposition apparatus has a plurality of said transmission mechanisms arranged therein in a symmetrical manner. Each transmission mechanism comprises: a drive shaft, formed with a tapered end; a driving wheel, configured with a shaft hole for the tapered end to bore coaxially therethrough; a plurality of slide pieces, radially mounted to the driving wheel; a first elastic member, mounted enabling the plural slide pieces to be ensheathed thereby; a second elastic member, disposed between the first elastic member and the first axial end of the drive shaft while being mounted to the periphery of the driving wheel; an enclosure, configured with an opening; wherein, the driving wheel that is moving in a reciprocating manner drives the sliding pieces to slide in radial directions, thereby, causing the outer diameter of the first elastic member to change accordingly and enabling the opening of the enclosure to open or close in consequence.

### CROSS-REFERENCE TO RELATED APPLICATION

This non-provisional application claims priority under 35 U.S.C. §119(a) on Patent Application No. 100109636 filed in Taiwan (R.O.C.) on Mar. 22, 2011, the entire contents of which are hereby incorporated by reference.

### TECHNICAL FIELD

The present disclosure relates to a transmission mechanism and the deposition apparatus using the same, and more particularly, to a transmission mechanism, capable of preventing its transmitting components from being polluted by reactive species that are ionized by process gases, so as to be used in an in-line type deposition apparatus for enhancing the reliability and improving the quality of the films that are deposited using the deposition apparatus.

### TECHNICAL BACKGROUND

For achieving cost and throughput advantages in optoelectronic industry, the substrates used in common in-line type film deposition apparatuses for solar cell production line are generally being transmitted inside and passing through a plurality of serially connected vacuum cavities by a transmitting means, such as an assembly of rollers. In addition, during the film deposition process, as the substrates are placed on hot plates for enabling the same to be heated uniformly, the quality as well as the uniformity of the resulting films can be greatly enhanced.

Please refer to FIG. 1, which is a schematic diagram showing a conventional film deposition apparatus. In FIG. 1, the film deposition apparatus 10 comprises: a frame 11, formed with a cavity 12; a plurality of driving wheel 13, disposed at two sides of the cavity while being configured respectively with an O-ring 131; a plurality of drive shafts 14, mounted on a rotary magnetic fluid feedthrough in a manner that each drive shaft 14 is axially connected to one corresponding driving wheel 13 while being connected to a substrate transmission mechanism 15. Thereby, when the drive shafts 14 as well as the driving wheels 13 are being driving to rotate by the substrate transmission mechanism 15, the substrates 18 that are placed on the driving wheels 13 will be brought along to move accordingly. Moreover, the frame 11 is further configured with a lifting mechanism 16, which has a hot plate 17 mounted on top thereof for allowing the hot plate 17 to be arranged inside the cavity 12. Operationally, the shower head 19 disposed inside the cavity 19 is activated to spray a process gas into the cavity 12, where it is ionized for depositing films on the substrates 18. During the film deposition process, for fulfilling the requirement of enabling the substrates 18 to move inside the in-line type film deposition apparatus 10 and also capable of placing the substrates 18 sequentially on the hot plate 17, the driving wheels 13 are designed to be retractable. However, as soon as the process gas is ionized into reactive species 191, the reactive species 191 not only will be driven to flow toward the substrate 18 for film depositing, but also will be spread all over the cavity 12. Therefore, if the components used for transmitting the substrates 18, which includes the rotary magnetic fluid feedthrough, are not properly shielded or protected, there will be deposit formed on any surface that is in contact with the reactive species, and with the progress of the film deposition process, those transmitting components will begin to act abnormally. For instance, the rotary magnetic fluid feedthrough can not rotate smoothly. Consequently, not only the frequency of equipment maintenance is increased, but also the cost relating to component replacement is increased. Moreover, the spreading reactive species 191 will also cause a fragile film to be formed on the surface of the O-ring 131 for each driving wheel 13, which is most like to break into small pieces by the transmitting of the substrates 18, resulting that the film deposition process is contaminated by the small pieces and thus the quality of the films that are deposited using the deposition apparatus are adversely affected.

There are already many improvements for film deposition apparatus in view of the aforesaid disadvantages. One of which is disclosed in U.S. Pat. Pub. No. 2010/0016136A1, entitled “Cover for a Roller”. As shown in FIG. 2 and FIG. 3, the roller 1 is designed to be refracted and thus received inside an enclosure 6 and when it is retracted, it will trigger a lever 3 to bring along a cover 2 to rotate about an axis 4 and thus close the opening of the enclosure 6 for sealing the roller 1 as well as an O-ring 5 mounted thereon inside the enclosure 6. Thereby, the roller 1 and the O-ring 5 can be protected from being contaminated by reactive species. Nevertheless, the other components, such as the axis 4 and the cover 2, are still exposed inside the cavity and are exposed to contact with the reactive species, so that there will be still fragile films to be formed on the surfaces of those components. Consequently, with the progress of the film deposition process, either movements relating to those components will begin to fail, or the fragile film is broken into dusts by the rotation of the movements relating to those components, resulting that the film deposition process is contaminated.

### TECHNICAL SUMMARY

The present disclosure relates to a transmission mechanism and a deposition apparatus using the same, by which the transmitting components, including driving wheels and shafts, can be prevented from being contaminated by reactive species that are generated from the ionization of a process gas in a film deposition process. In addition, since the transmitting components of the transmission mechanism are sealed from contacting with the reactive species, the transporting of substrates in any in-line type film deposition apparatus, including CVD apparatuses, PECVD apparatuses and PVD apparatuses, can be ensured to function smoothly, and thereby, not only the production yield of the film deposition apparatus is increased since the frequency of equipment maintenance and also the running cost relating to component replacement are both decreased, but also the contamination to the deposition cavity and the substrate surfaces due to the breaking off of the reactive species attached to the driving wheels and O-rings that are engaged with the substrates can be prevented, and thus the reliability of the deposition apparatus as well as the quality of the films that are deposited using the deposition apparatus are enhanced.

To achieve the above object, the present disclosure provides a transmission mechanism, comprising: a drive shaft, axially formed with a tapered end while enabling the tapered end to be configured with at least one cone; a driving wheel, having a first axial end and a second axial end formed opposite to each other on the center axis thereof while being configured with a shaft hole on the first axial end so as to be provided for the tapered end of the drive shaft to bore coaxially therethrough; a coupler, for connecting the drive shaft to the driving wheel for enabling the driving wheel to rotate synchronously with the drive shaft and also enabling the driving wheel to move relative to the drive shaft in a direction parallel to the center axis of the driving wheel; a plurality of slide pieces, each slide piece being further configured with a first end and a second end that are disposed opposite to each other while allowing an axis of the relating slide piece to extend and form between the two, and the plural slide pieces being arranged radially mounted to the driving wheel while enabling their axes to center to the center axis of the driving wheel in a manner that the first ends are orientated facing toward the center axis of the driving wheel while being exposed inside the shaft hole of the drive shaft, and the second ends to exposed outside the periphery of the driving wheel; a first elastic member, being disposed inside the driving wheel while abutting against the second ends of the plural slide pieces for encasing the same; a second elastic member, disposed between the first elastic member and the first axial end of the driving wheel while being mounted to the periphery of the driving wheel; and an enclosure, for receiving the drive shaft, the driving wheel, the plural slide pieces, the first elastic member and the second elastic member therein, being configured with an opening that is arranged for allowing the second axial end of the driving wheel to be exposed therein; wherein, when the driving wheel and the drive shaft are being activated to move relatively to each other, the first ends of the sliding pieces will be brought along to move relatively to the tapered end of the drive shaft, and thus, cause the plural slide pieces to slide radially with respect to the driving wheel, causing the outer diameter of the first elastic member to change accordingly while enabling the opening of the enclosure to open or close in consequence.

To achieve the above object, the present disclosure provides a deposition apparatus, comprising: a cavity, provided for enabling a process gas to be ionized therein into reactive species; and a plurality of transmission mechanisms, being arranged inside the cavity in a symmetrical manner to be used for transporting at least one substrate while allowing a film deposition process to be performed upon the at least one substrate using the reactive species, and each transmission mechanism further comprising: a drive shaft, axially formed with a tapered end while enabling the tapered end to be configured with at least one cone; a driving wheel, having a first axial end and a second axial end formed opposite to each other on the center axis thereof while being configured with a shaft hole on the first axial end so as to be provided for the tapered end of the drive shaft to bore coaxially therethrough; a coupler, for connecting the drive shaft to the driving wheel for enabling the driving wheel to rotate synchronously with the drive shaft and also enabling the driving wheel to move relative to the drive shaft in a direction parallel to the center axis of the driving wheel; a plurality of slide pieces, each slide piece being further configured with a first end and a second end that are disposed opposite to each other while allowing an axis of the relating slide piece to extend and form between the two, and the plural slide pieces being arranged radially mounted to the driving wheel while enabling their axes to center to the center axis of the driving wheel in a manner that the first ends are orientated facing toward the center axis of the driving wheel while being exposed inside the shaft hole of the drive shaft, and the second ends to exposed outside the periphery of the driving wheel; a first elastic member, being disposed inside the driving wheel while abutting against the second ends of the plural slide pieces for encasing the same; a second elastic member, disposed between the first elastic member and the first axial end of the driving wheel while being mounted to the periphery of the driving wheel; and an enclosure, for receiving the drive shaft, the driving wheel, the plural slide pieces, the first elastic member and the second elastic member therein, being configured with an opening that is arranged for allowing the second axial end of the driving wheel to be exposed therein; wherein, when the driving wheel and the drive shaft are being activated to move relatively to each other, the first ends of the sliding pieces will be brought along to move relatively to the tapered end of the drive shaft, and thus, cause the plural slide pieces to slide radially with respect to the driving wheel, causing the outer diameter of the first elastic member to change accordingly while enabling the opening of the enclosure to open or close in consequence.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic diagram showing a conventional film deposition apparatus.

FIG. 2 and FIG. 3 are schematic diagrams showing a device disclosed in U.S. Pat. Pub. No. 2010/0016136A1, entitled “Cover for a Roller”.

FIG. 4 is a schematic diagram showing a deposition apparatus according to an embodiment of the present disclosure.

FIG. 5 is a cross sectional diagram showing a transmission mechanism of the present disclosure when its driving wheel is positioned at a first position.

FIG. 6 shows an A-A section of FIG. 5, that is a complete axial cross section of the transmission mechanism of FIG. 5.

FIG. 7 is a schematic diagram showing how the slide pieces are assembled driving wheel in the present disclosure.

FIG. 8 is a cross sectional diagram showing a transmission mechanism of the present disclosure when its driving wheel is positioned at a second position.

FIG. 9 shows a B-B section of FIG. 8, that is a complete axial cross section of the transmission mechanism of FIG. 8.

FIG. 10 is a schematic diagram of a deposition apparatus while the driving wheels of its transmission mechanisms are positioned at their second positions according to the present disclosure.

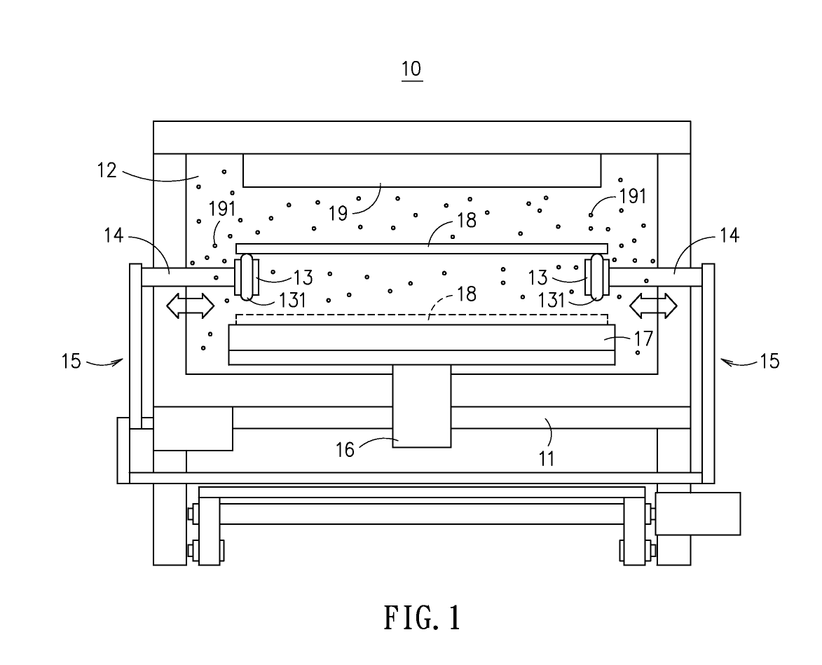

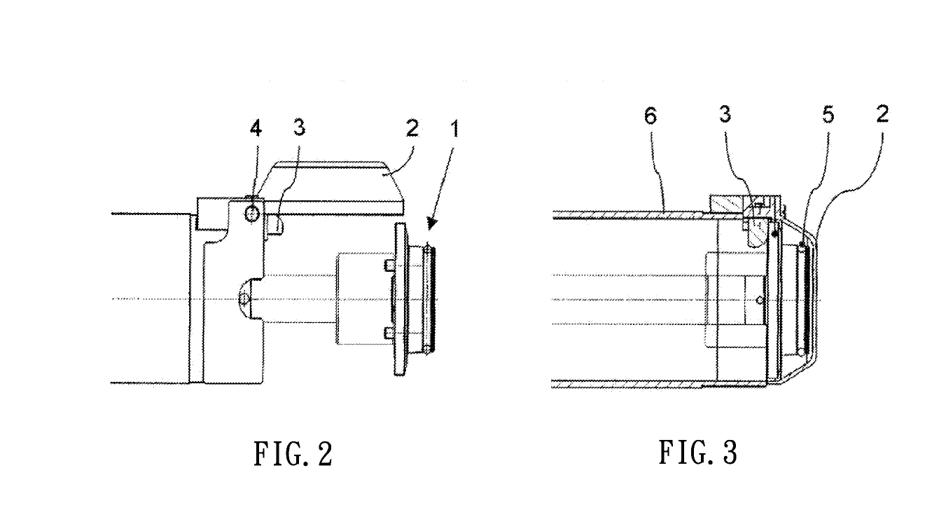

### DESCRIPTION OF THE EXEMPLARY EMBODIMENTS

For your esteemed members of reviewing committee to further understand and recognize the fulfilled functions and structural characteristics of the disclosure, several exemplary embodiments cooperating with detailed description are presented as the follows.

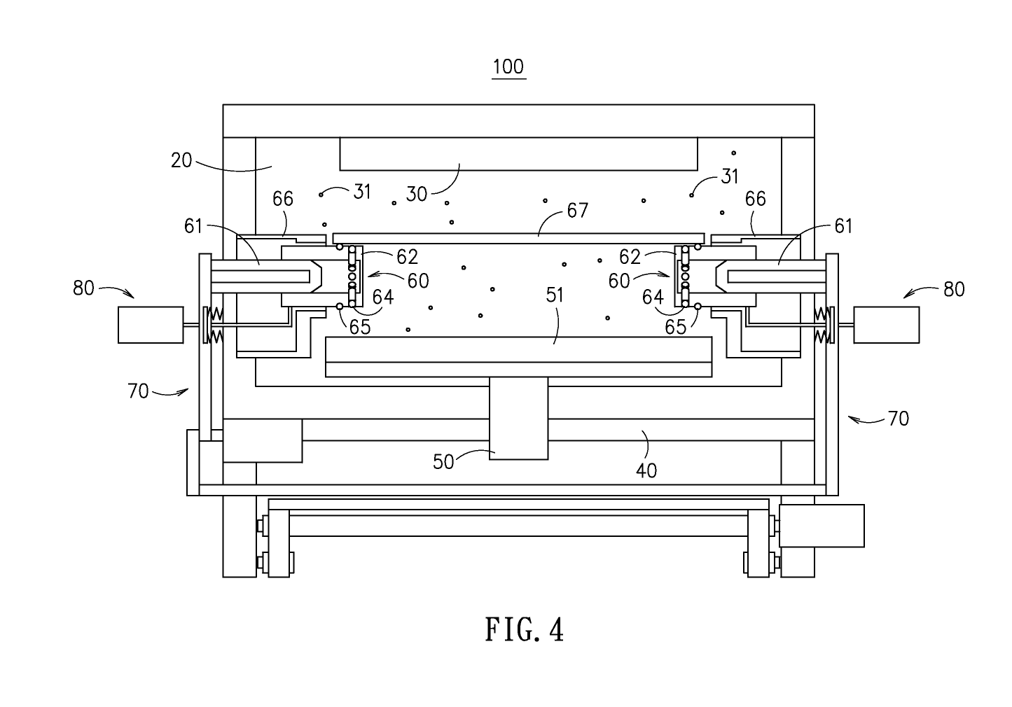

Please refer to FIG. 4, which is a schematic diagram showing a deposition apparatus according to an embodiment of the present disclosure. In FIG. 4, a deposition apparatus 100 is configured with a cavity 20, which has a shower head 30 disposed therein for spraying a process gas into the cavity 20 where it is further being ionized into reactive species 31. Moreover, the cavity 20 is mounted on a frame 40, whereas the frame 40 is configured with a lifting mechanism 50 that is provided for a hot plate 51 to be arranged on top thereof while enabling the same to be arranged inside the cavity 20. In addition, there is a plurality of transmission mechanisms 60 being arranged symmetrically inside the cavity 20 at two opposite sides thereof.

As shown in FIG. 4 to FIG. 6, each of the plural transmission mechanisms 60 comprises: a drive shaft 61, a driving wheel 62, a plurality of slide pieces 63, a first elastic member 64, a second elastic member 65 and an enclosure 66.

In an embodiment, the drive shaft 61 is substantially a cylinder formed with an axis center C, and a cones-shaped tapered end 611 that is coaxially arranged along with the axis center C. Moreover, the tapered end 611 is configured with at least one conical surface 612. As shown in FIG. 4, the drive shaft 61 is connected to a first driving device 70 so that the drive shaft can be driven to rotate. It is noted that the first driving device 70 can be an assembly of motors and belts, but is not limited thereby.

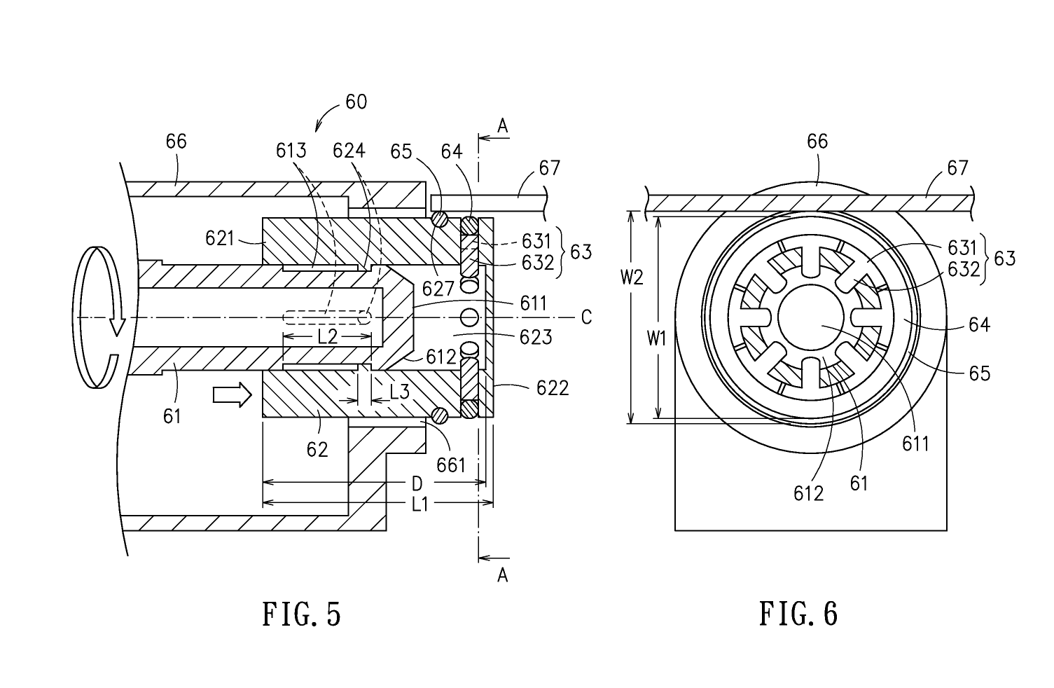

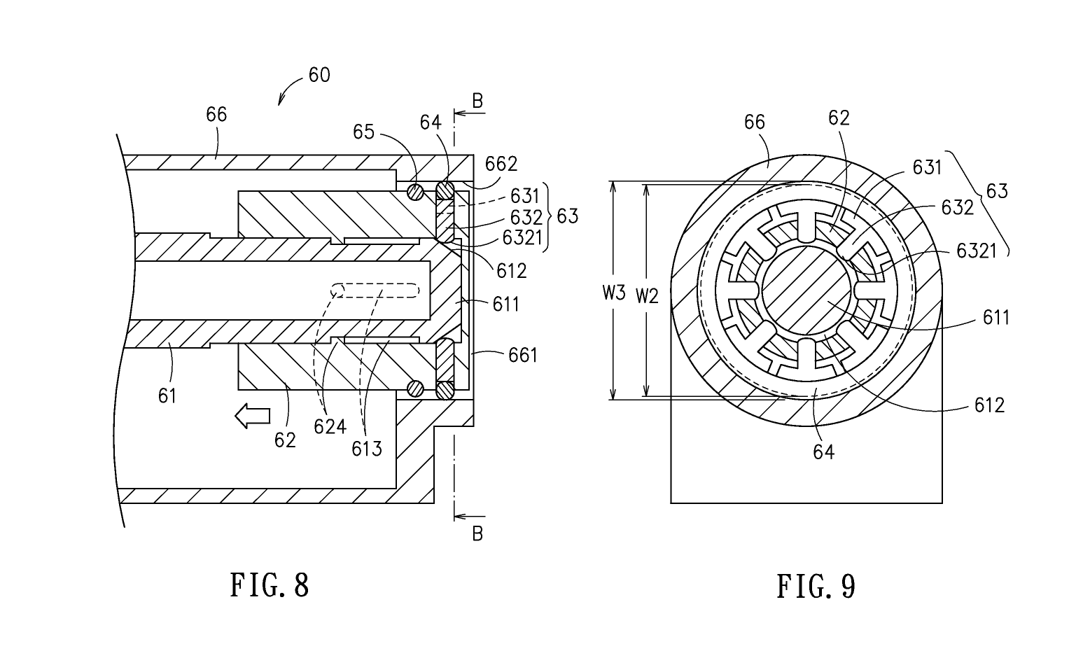

The driving wheel 62, being formed as a cylinder, is coaxially arranged with the drive shaft 61, so that the center axis C of the drive shaft 61 is the center axis of its corresponding driving wheel 62. Moreover, the driving wheel 62 which is formed extending by a length L1 along its center axis C is configured with a first axial end 621 and a second axial end 622 at positions opposite to each other on the center axis C. In addition, the driving wheel 62 further has a shaft hole 623 formed at its first axial end 621 by a depth D smaller than the length L1 of the driving wheel 62 (D<L1). That is, the shaft hole 623 is not formed boring through the whole driving wheel 62 and reaching the second axial end 622. Thereby, the tapered end 611 of the drive shaft 61 is coaxially arranged inside the shaft hole 623. As shown in FIG. 4, the driving wheel 62 is connected to a second driving device 80, by that the driving wheel 62 can be driven to move in a reciprocating manner between a first position and a second position in a direction parallel to the center axis C of the driving wheel 62. As shown in FIG. 5, the driving wheel 62 is positioned at a first position and that is when substrates 67 are being transported. As shown in FIG. 8, the driving wheel 62 is positioned at a second position. It is noted that the second driving device 80 can be a pneumatic device or a hydraulic device, but is not limited thereby.

There is at least one a coupler being arranged between the drive shaft 61 and the driving wheel 62. As the embodiment shown in FIG. 5, the coupler is composed of a groove 613 and a protruding key 624 in a manner that the groove 613 is formed on the drive shaft 61 that is extending by of a length L2 in a direction parallel to the center axis C of the driving wheel 62; and the protruding key 624 is disposed inside the shaft hole 623 at a position corresponding to the groove 613 that is extending by a length L3 also in a direction parallel to the center axis C of the driving wheel 62. Moreover, the length L3 of the protruding key 624 is smaller than the length L2 of the groove 613. As the protruding key 624 is designed to be inset into the groove 613 so as to construct a coupler for connecting the driving wheel 62 to the drive shaft 61, the driving wheel 62 can be driven to rotate in synchronization with the drive shaft 61 when the drive shaft 61 is being driven to rotate by the first driving device 70. In addition, when the driving wheel 62 is being driven to move by the second driving device 80 in a reciprocating manner between the first position and the second position in a direction parallel to the center axis C of the driving wheel 62, as shown in FIG. 5 and FIG. 8, the protruding key 624 will be located right at the two ends of the groove 613 in respective corresponding to driving wheel 62 when it is located at the first position and the second position, by that the grove 613 not only can function for stabilizing the driving wheel 62 when it is being driven to move, but also it can function as a position limit for restricting the moving range of the driving wheel 62. It is noted that the driving wheel 62 is disposed for allowing the same to rotate while capable of moving relative to the drive shaft 61 in a direction parallel to the center axis C of the driving wheel 62, and therefore, the aforesaid coupler comprising the groove 613 and the protruding key 624 is only one embodiment for enabling the driving wheel 62 to move as it is designed to do. Thus, it is possible to formed the groove 613 and the protruding key 624 respectively on the driving wheel 62 and the drive shaft 61, and still accomplish the same purpose t for enabling the driving wheel 62 to move as it is designed to do. Moreover, there is no restriction relating to the amount of the groove 613 and protruding key 624, that they can be determined according to actual requirement.

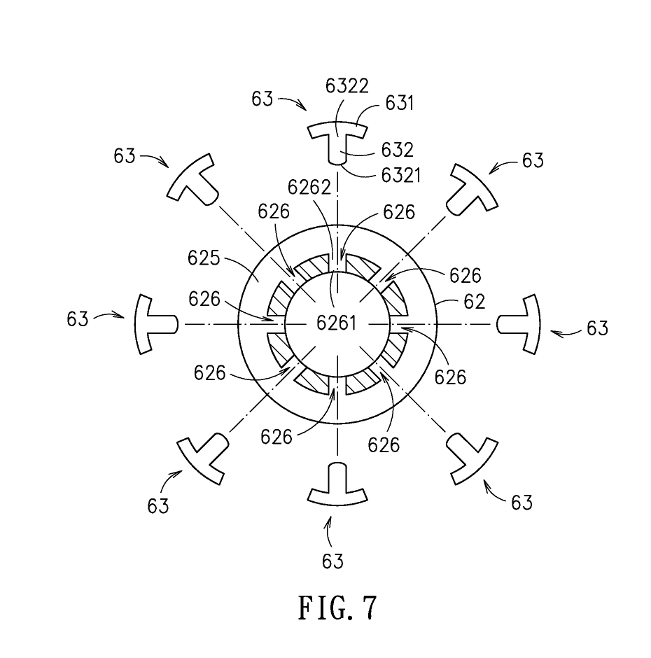

As shown in FIG. 5 to FIG. 7, the driving wheel 62 is further configured with a first groove 625 and a plurality of guide holes 626 in a manner that the first groove 625 is disposed surrounding the periphery of the driving wheel 62 while centering to the center axis C of the same, and the plural guide holes 626 are radially and equiangularly disposed on the driving wheel 62 centering to the center axis C of the same, whereas each guide hole 626 is axially configured with a first end 6261 and a second end 6262 that are disposed opposite to each other while allowing the first end 6261 to be arranged in communication with the shaft hole 623, and the second end 6262 to be arranged in communication with the first groove 625.

Moreover, in an embodiment of the present disclosure, each of the slide piece 63 is configured with a support element 631 and a guide post 632, whereas the guide post 632 is axially configured with a first end 6321 and a second end 6322 that are disposed opposite to each other, and the support element 631 is disposed at the second end 6322 of the guide post 632. In this embodiment, the support element 631 is an arc-shape object, and the second end 6322 of the guide post 632 is arranged at the middle of the arc-shaped support element 631, so that the resulting slide piece 63 is formed substantially as a T-shape structure whose guide post 632 is disposed inside the guide hole 626 and the support element 631 is arranged inside the first groove 625. In this embodiment, there are eight guide holes 626. The amount of slide piece 63 should be the same as that of the guide hole 626, and all those slide pieces 63 should be formed of the same shape that the first end 6321 of the guide post 632 is substantially defined to be the first end of the slide piece 63 while the support element 631 is substantially defined to be the second end of the slide piece 63. Thus, each slide piece 63 is further configured with a first end and a second end that are disposed opposite to each other while allowing an axis of the relating slide piece 63 to extend and form between the two. It is noted that the aforesaid axis is substantially the center axis of the guide post 632; and as the plural guide holes are radially and equiangularly disposed on the driving wheel 62 centering to the center axis C of the same, the plural slide pieces 63 can be radially mounted to the driving wheel 62 while enabling their axes to center to the center axis C of the driving wheel 62 in a manner that the first ends are orientated facing toward the center axis C of the driving wheel 62 while being exposed inside the shaft hole 623 of the driving wheel shaft 62, and the second ends to exposed outside the periphery of the driving wheel 62. In addition, the first elastic member 64 is disposed inside the first groove 625 of the driving wheel 62 while abutting against the peripheries of the plural slide pieces 63 for encasing the same.

As shown in FIG. 5 and FIG. 6, the first elastic member 64 is disposed inside the first groove 625 of the driving wheel 62 while abutting against the support elements 631 of the plural slide pieces 63 for encasing the same, and the second elastic member 65 is mounted on the periphery of the driving wheel 62 between the first elastic member 64 and the first axial end 621 of the drive shaft 61. As shown in FIG. 5, the second groove 627 is provided for receiving the second elastic member 65. Moreover, the second elastic member 65 is concentrically arranged with the first elastic member 64, and also the second elastic member 65 is disposed at a position proximate to the first axial end 621 of the driving wheel 62. It is noted that both the first and the second elastic members 64, 65 can be O-rings, which are able to expand and contract elastically. In addition, the enclosure 66 is used for receiving the drive shaft 61, the driving wheel 62, the plural slide pieces 63, the first elastic member 64 and the second elastic member 65 therein, and is configured with an opening 661 that is arranged for allowing the second axial end 622 of the driving wheel 62 to be exposed therein while protruding outside the opening 661 by a length when the driving wheel 62 is positioned at the first position, as shown in FIG. 5. Moreover, when the driving wheel 62 is positioned at the first position, the first elastic member 64 and the second elastic member 65 are exposed outside the enclosure 66, the first end 6321 of the guide post 632 of each slide piece 63 will be detached from contacting with the conical surface 612 of the tapered end 611 of the drive shaft 61, and thus, by the resilience the first elastic member 64 that is tightly fitted on the peripheries of the plural slide pieces 63, the plural guide posts 63 will be forced to move inside their corresponding guide holes 626 in a direction toward the center axis C of the driving wheel 62. Consequently, as the outer diameter W1 of the first elastic member 64 is smaller than the outer diameter W2 of the second elastic member 65, as shown in FIG. 6, the second elastic member 65 will be arranged slightly protruding out of the driving wheel 62, so that the substrates 67 can be supported by the second elastic member 65 and thus can be moved along with the rotation of the driving wheel 62. As shown in FIG. 4, each substrate 67 is moved into the cavity 20 by the plural transmission mechanisms 60 that are symmetrically arranged.

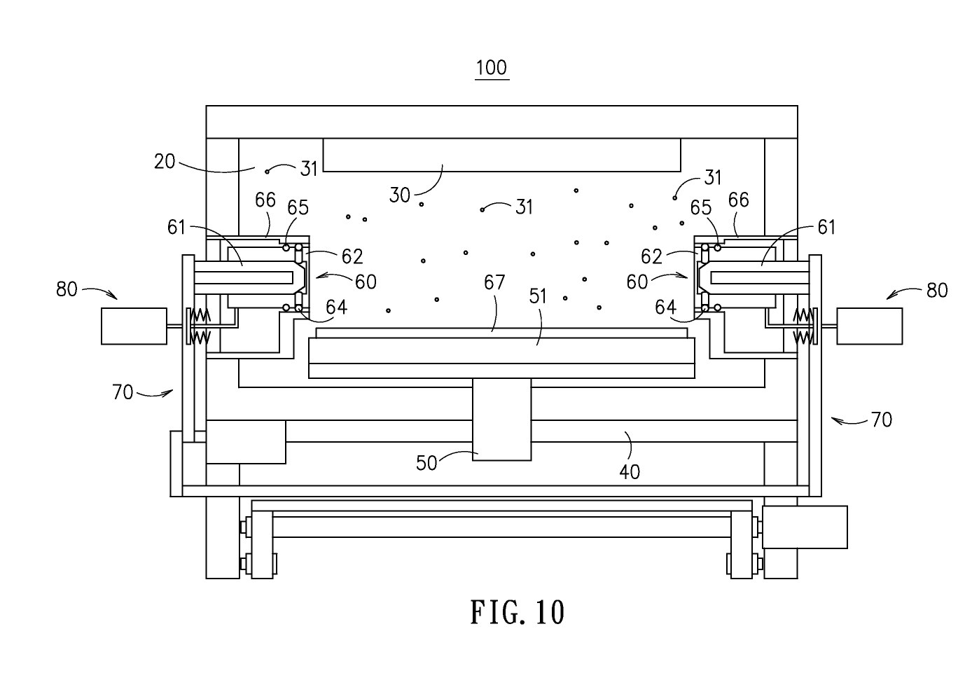

As shown in FIG. 8 to FIG. 10, when the driving wheel 62 is positioned at the second position, i.e. the driving wheel 62 is retracted into the enclosure 66, the first end of the slide piece 63, i.e. the first end 6321 of the guide post 632, is driven to move toward the tapered end 611 of the drive shaft 61, and when the slide pieces 63 are engaged with the conical surface 612, they will be pushed by the conical surface 612 for enabling the plural slide pieces 63 to move radially toward the outer periphery of the driving wheel 62 while allowing the first elastic member 64 to be stretched by the support elements 631 of the slide pieces 63, resulting that the outer diameter of the first elastic member 64 is enlarged while allowing the first elastic member 64 to be sandwiched between the support elements 631 and the inner sidewall 662 of the enclosure 66. Thereby, the opening 661 of the enclosure 66 is closed while enabling the outer diameter W3 of the first elastic member 64 to be larger than the outer diameter W2 of the second elastic member 65. It is noted that the first elastic member 64 is stretched uniformly and is arranged tightly abutting against the inner sidewall 662 of the enclosure 66. As shown in FIG. 10, when the substrate 67 is heated on the hot plate 51, although the cavity 20 is filled with reactive species 31, the transmission mechanism 60 can be prevented from being contaminated by the reactive species 31 since the opening 661 of the enclosure 66 is closed.

Comparing the arrangement of FIG. 6 with the arrangement of FIG. 9 as the driving wheel 62 is move in a reciprocating manner between the first position and the second position, the first ends of the plural slide pieces 63, i.e. the first ends 6321 of the guide posts 632, are driven to move relative to the tapered end 611 of the drive shaft 61. Consequently, the slide pieces 63 will be pushed to move radially by the conical surface 612, and thereby, causing the outer diameter of the first elastic member 64 to change accordingly and enabling the opening 661 of the enclosure 66 to open or close in consequence.

To sum up, the present disclosure relates to a transmission mechanism and a deposition apparatus using the same, by which the transmitting components, including driving wheels and shafts, can be prevented from being contaminated by reactive species that are generated from the ionization of a process gas in a film deposition process. In addition, since the transmitting components of the transmission mechanism are sealed from contacting with the reactive species, the transporting of substrates in any in-line type film deposition apparatus, including CVD apparatuses, PECVD apparatuses and PVD apparatuses, can be ensured to function smoothly, and thereby, not only the operation ratio of the film deposition apparatus is increased since the frequency of equipment maintenance and also the cost relating to component replacement are both decreased, but also the contamination to the deposition cavity and the substrate surfaces due to the breaking off of the reactive species attached to the driving wheels and O-rings that are engaged with the substrates can be prevented, and thus the reliability of the deposition apparatus as well as the quality of the films that are deposited using the deposition apparatus are enhanced.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A transmission mechanism, comprising:
a drive shaft, axially formed with a tapered end while enabling the tapered end to be configured with at least one conical surface;
a driving wheel, having a first axial end and a second axial end formed opposite to each other on the center axis thereof while being configured with a shaft hole on the first axial end so as to be provided for the tapered end of the drive shaft to bore coaxially therethrough;
a coupler, for connecting the drive shaft to the driving wheel for enabling the driving wheel to rotate synchronously with the drive shaft and also enabling the driving wheel to move relative to the drive shaft in a direction parallel to the center axis of the driving wheel;
a plurality of slide pieces, each slide piece being further configured with a first end and a second end that are disposed opposite to each other while allowing an axis of the relating slide piece to extend and form between the two, and the plural slide pieces being arranged radially mounted to the driving wheel while enabling their axes to center to the center axis of the driving wheel in a manner that the first ends are orientated facing toward the center axis of the driving wheel while being exposed inside the shaft hole of the driving wheel, and the second ends to exposed outside the periphery of the driving wheel;
a first elastic member, being disposed inside the driving wheel while abutting against the second ends of the plural slide pieces for encasing the same;
a second elastic member, disposed between the first elastic member and the first axial end of the driving wheel while being mounted to the periphery of the driving wheel; and
an enclosure, for receiving the drive shaft, the driving wheel, the plural slide pieces, the first elastic member and the second elastic member therein, being configured with an opening that is arranged for allowing the second axial end of the driving wheel to be exposed therein;
wherein, when the driving wheel and the drive shaft are being activated to move relatively to each other, the first ends of the sliding pieces will be brought along to move relatively to the tapered end of the drive shaft, and thus, cause the plural slide pieces to slide radially with respect to the driving wheel, causing the outer diameter of the first elastic member to change accordingly while enabling the opening of the enclosure to open or close in consequence.

2. The transmission mechanism of claim 1, wherein the driving wheel is further configured with a first groove, provided for the first elastic member to be arranged therein, and a plurality of guide holes in a manner that the first groove is disposed surrounding the periphery of the driving wheel while centering to the center axis of the same, and the plural guide holes are radially disposed on the driving wheel centering to the center axis of the same, whereas each guide hole is axially configured with a first end and a second end that are disposed opposite to each other while allowing the first end to be arranged in communication with the shaft hole, and the second end to be arranged in communication with the first groove; and also, each of the slide piece is configured with a support element and a guide post in a manner that the guide post is arranged coaxial to the center axis of the corresponding slide piece while being disposed inside one of the plural guide holes corresponding thereto, whereas the guide post is axially configured with a first end and a second end that are disposed opposite to each other, and the support element is disposed at the second end of the guide post while being inset into the first groove, and thereby, the first end of the guide post is substantially defined to be the first end of the slide piece while the support element is substantially defined to be the second end of the slide piece.

3. The transmission mechanism of claim 2, wherein each support element is an arc-shaped unit, and the moving of the driving wheel and the drive shaft relative to the drive shaft is performed by activating the driving wheel to move in a reciprocating manner between a first position and a second position in the direction parallel to the center axis of the driving wheel; and when the driving wheel is positioned at the second position, the assembly of the arcs of the arc-shaped supporting elements forms a circle.

4. The transmission mechanism of claim 2, wherein the plural guide holes are equiangularly disposed, and in an amount equal to the amount of the slide pieces, while the plural slide pieces are formed of the same shape.

5. The transmission mechanism of claim 1, wherein the coupler further comprises:
at least one groove, each formed on the drive shaft while extending by a length in a direction parallel with the center axis of the drive shaft; and
at least one protruding key, each disposed inside the shaft hole of the driving wheel at a position corresponding to the groove while extending by a length in a direction parallel with the center axis of the driving wheel in a manner that the length of the protruding key is smaller than that of the corresponding groove for allowing the protruding key to inset into the groove.

6. The transmission mechanism of claim 1, wherein the tapered end of the drive shaft is formed as a cone.

7. The transmission mechanism of claim 1, wherein the second elastic member is concentrically arranged with the first elastic member.

8. The transmission mechanism of claim 1, wherein the first and the second elastic members are O-rings.

9. The transmission mechanism of claim 1, wherein the driving wheel is formed extending along its center axis by a length, while allowing the shaft hole to be formed with a depth smaller than the length.

10. The transmission mechanism of claim 1, wherein the drive shaft is connected to a first driving device so as to be driven to rotate thereby; and the driving wheel is connected to a second driving device so as to be driven to move in a reciprocating manner in the direction parallel to the center axis of the driving wheel.

11. A deposition apparatus, comprising:
a cavity, provided for enabling a process gas to be ionized therein into reactive species; and
a plurality of transmission mechanisms, being arranged inside the cavity in a symmetrical manner to be used for transporting at least one substrate while allowing a film deposition process to be performed upon the at least one substrate using the reactive species, and each transmission mechanism further comprising:
a drive shaft, axially formed with a tapered end while enabling the tapered end to be configured with at least one conical surface;
a driving wheel, have a first axial end and a second axial end formed opposite to each other on the center axis thereof while being configured with a shaft hole on the first axial end so as to be provided for the tapered end of the drive shaft to bore coaxially therethrough;
a coupler, for connecting the drive shaft to the driving wheel for enabling the driving wheel to rotate synchronously with the drive shaft and also enabling the driving wheel to move relative to the drive shaft in a direction parallel to the center axis of the driving wheel;
a plurality of slide pieces, each slide piece being further configured with a first end and a second end that are disposed opposite to each other while allowing an axis of the relating slide piece to extend and form between the two, and the plural slide pieces being arranged radially mounted to the driving wheel while enabling their axes to center to the center axis of the driving wheel in a manner that the first ends are orientated facing toward the center axis of the driving wheel while being exposed inside the shaft hole of the driving wheel, and the second ends to exposed outside the periphery of the driving wheel;
a first elastic member, being disposed inside the driving wheel while abutting against the second ends of the plural slide pieces for encasing the same; a second elastic member, disposed between the first elastic member and the first axial end of the drive shaft while being mounted to the periphery of the driving wheel; and
an enclosure, for receiving the drive shaft, the driving wheel, the plural slide pieces, the first elastic member and the second elastic member therein, being configured with an opening that is arranged for allowing the second axial end of the driving wheel to be exposed therein;
wherein, when the driving wheel and the drive shaft are being activated to move relatively to each other, the first ends of the sliding pieces will be brought along to move relatively to the tapered end of the drive shaft, and thus, cause the plural slide pieces to slide radially with respect to the driving wheel, causing the outer diameter of the first elastic member to change accordingly while enabling the opening of the enclosure to open or close in consequence.
